(19) United States
(12) Patent Application Publication
(10) Pub. No.: US 2024/0329207 A1
(43) Pub. Date: Oct. 3, 2024

(54) VEHICLE UPPER STRUCTURE

(71) Applicant: TOYODA GOSEI CO., LTD., Kiyosu-shi (JP)

(72) Inventors: Yosuke TSUCHIYA, Kiyosu-shi (JP); Koji FUKAGAWA, Kiyosu-shi (JP); Risa HIRANO, Kiyosu-shi (JP); Masaya ITO, Kiyosu-shi (JP); Yuji SUMI, Kiyosu-shi (JP); Toyokazu NOHARA, Nagoya-shi (JP)

(21) Appl. No.: 18/609,047

(22) Filed: Mar. 19, 2024

(30) Foreign Application Priority Data
Apr. 3, 2023 (JP) 2023-060212

(51) Int. Cl. G01S 7/481; G01S 7/497; G01S 17/931; H05K 7/20

(52) U.S. Cl. CPC G01S 7/4813; G01S 7/497; G01S 17/931; H05K 7/20863; H05K 7/20872; G01S 2007/4977

(57) ABSTRACT

A vehicle upper structure includes a roof member of a vehicle, a sensor, a sensor cover, and an external cover. The sensor is mounted on an upper part of the vehicle such that at least part of the sensor is located above the roof member. The sensor is configured to emit and receive electromagnetic waves to recognize the external environment of the vehicle. The sensor cover covers at least the part of the sensor that is above the roof member. The external cover covers the sensor cover from outside with a gap between the external cover and the sensor cover.

### BACKGROUND

### 1. Field

The present disclosure relates to a vehicle upper structure in which a sensor that recognizes an external environment of a vehicle is mounted in an upper portion of the vehicle.

### 2. Description of Related Art

For example, a typical vehicle includes an opening member in an upper portion. The opening member incorporates a sensor that emits and receives electromagnetic waves to recognize the external environment.

In the above-described vehicle, the sensor is only covered by the opening member. Thus, the strength of the section covering the sensor may not be sufficiently high. Thus, when an external force is applied to the opening member, the opening member may fail to function properly to protect the sensor from the external force.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a vehicle upper structure includes a roof member of a vehicle, a sensor, a sensor cover, and an external cover. The sensor is mounted on an upper part of the vehicle such that at least part of the sensor is located above the roof member. The sensor is configured to emit and receive electromagnetic waves to recognize an external environment of the vehicle. The sensor cover covers at least the part of the sensor that is above the roof member. The external cover covers the sensor cover from outside with a gap between the external cover and the sensor cover.

Other features and aspects will be apparent from the following detailed description, the drawings, and the claims.

### BRIEF DESCRIPTION OF THE DRAWINGS

FIG. 1 is a schematic side view of a vehicle in which a vehicle upper structure is employed in a first embodiment.

FIG. 2 is a schematic plan view of the vehicle shown in FIG. 1.

FIG. 3 is a partial cross-sectional side view of the vehicle upper structure according to the first embodiment.

FIG. 4 is an enlarged view of section X in FIG. 3.

FIG. 5 is an enlarged view of section Y in FIG. 3.

FIG. 6 is an exploded partial cross-sectional side view of components of the vehicle upper structure according to the first embodiment.

FIG. 7 is a partial cross-sectional side view of a vehicle upper structure according to a second embodiment.

FIG. 8 is a partial cross-sectional side view of a vehicle upper structure according to a third embodiment.

FIG. 9 is a partial cross-sectional side view of a vehicle upper structure according to a fourth embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, except for operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### FIRST EMBODIMENT

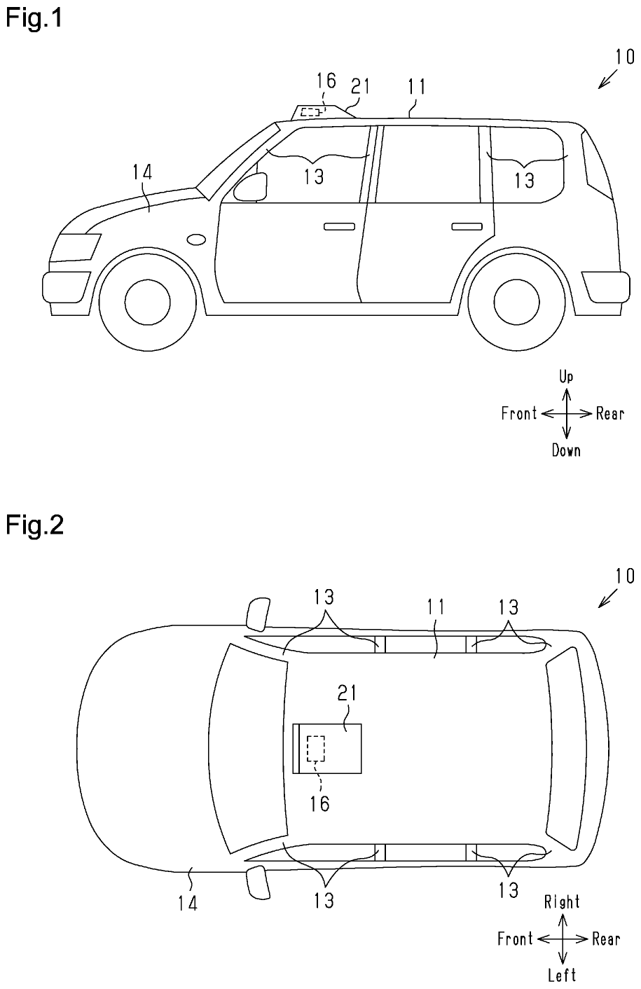

A vehicle upper structure according to a first embodiment will now be described with reference to FIGS. 1 to 6.

In the following description, the direction in which a vehicle 10 advances forward will be referred to as the front, and the reverse direction will be referred to as the rear. The vertical direction refers to the vertical direction of the vehicle 10, and the left-right direction refers to the vehicle width direction that corresponds with the left-right direction when the vehicle 10 is advancing forward.

The vehicle 10 shown in FIGS. 1 and 2 is not limited to a vehicle with an internal combustion engine as a drive source, but may be, for example, an electric vehicle with an electric motor as a drive source or a hybrid electric vehicle with an internal combustion engine and an electric motor as drive sources.

The vehicle 10 includes a plate-shaped roof member 11 and elongated pillars (pillar portions) 13 in an upper portion of the vehicle 10. The roof member 11 includes at least a part of a roof disposed above the passenger compartment of the vehicle 10. The roof member 11 protects occupants from rain, wind, snow, and sunlight. The pillars 13 function to ensure the strength of the vehicle body 14 while supporting the roof member 11 from below.

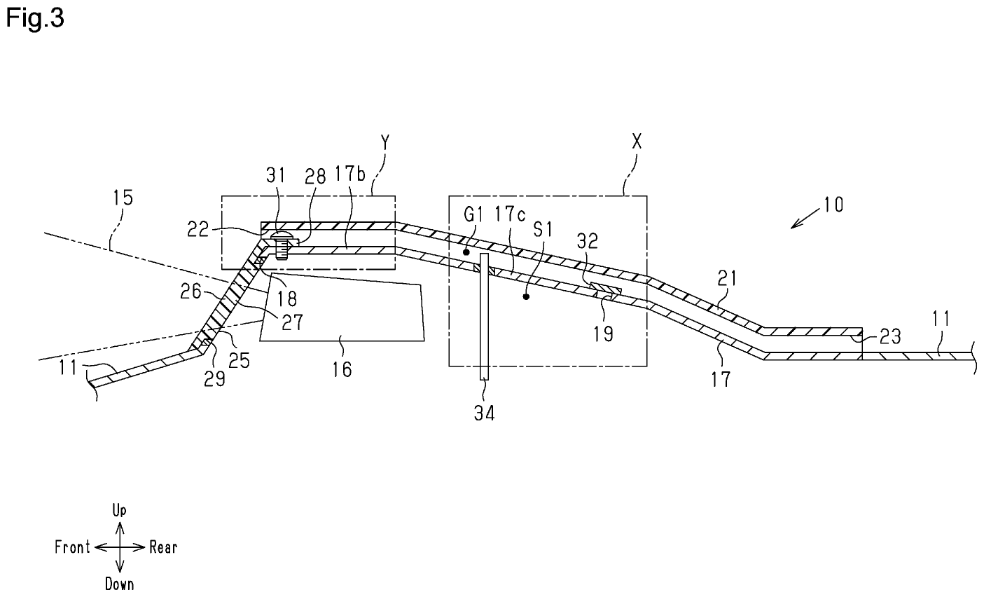

As shown in FIGS. 2 and 3, a sensor 16 is mounted on the front part of the roof member 11. The sensor 16 is located in a section in the lateral direction, at the center in the first embodiment. The sensor 16 emits and receives electromagnetic waves to recognize the external environment of the vehicle 10.

### Sensor 16

The sensor 16 is mounted in an upper portion of the vehicle 10 such that at least part of the sensor 16 is located above the roof member 11. In the first embodiment, the sensor 16 includes a light detection and ranging (LiDAR) device. To recognize the external environment, a LiDAR device uses infrared rays as electromagnetic waves.

The sensor 16 has a sensor function of emitting infrared rays 15 to the outside of the vehicle 10, specifically, toward a prescribed angular range in front of the vehicle 10, and receiving the infrared rays 15 that have struck and have been reflected by an object outside the vehicle 10.

As described above, the sensor 16 emits the infrared rays 15 forward from the vehicle 10. Thus, the emission direction of the infrared rays 15 from the sensor 16 is the direction from the rear toward the front of the vehicle 10. The front in the emission direction of the infrared rays 15 substantially agrees with the forward direction of the vehicle 10. The rear in the emission direction also substantially agrees with the rear of the vehicle 10. Accordingly, in the following description, the front in the emission direction of the infrared rays 15 will simply be referred to as “front” or “forward.” The rear in the emission direction will simply be referred to as “rear” or “rearward.”

The vehicle upper structure includes the roof member 11 and the sensor 16. The vehicle upper structure further includes a sensor cover 17, an external cover 21, and a decorative component 25.

### Sensor Cover 17

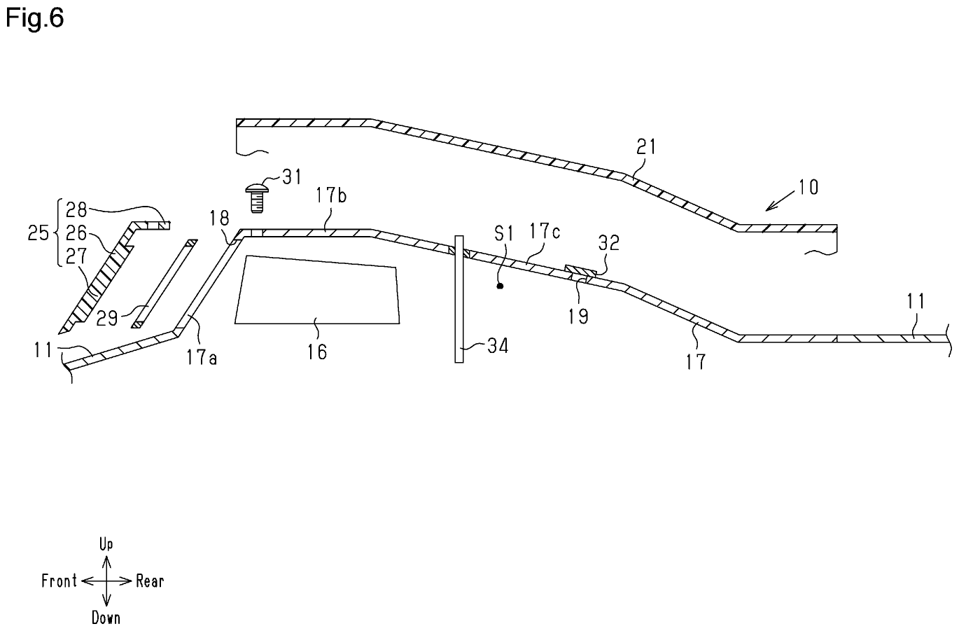

As shown in FIGS. 3 and 6, the sensor cover 17 has a shape that covers at least a part of the sensor 16 that is above the roof member 11. The sensor cover 17 is entirely made of a metal material. The sensor cover 17 includes a front portion 17a at its front part. The front portion 17a is located in front of the sensor 16 in the emission direction of the infrared rays 15. The front portion 17a is inclined relative to a horizontal plane (not shown) and a vertical plane (not shown) so as to be progressively shifted to the front toward the lower end. An opening 18 is formed between the front portion 17a and a section of the roof member 11 that is adjacent to and in front of the front portion 17a. The sensor cover 17 includes a top 17b in a section adjacent to and rearward of the front portion 17a. The top 17b extends rearward from the rear upper end of the front portion 17a. Further, the sensor cover 17 includes a rear portion 17c at a section adjacent to and rearward of the top 17b. The rear portion 17c is inclined to be lower toward the rear end.

### External Cover 21

The external cover 21 covers the sensor cover 17 from outside with a gap G1 between the external cover 21 and the sensor cover 17. The size of the gap G1 may be constant regardless of the positions of the sensor cover 17 and the external cover 21, or may vary depending on the positions. The external cover 21 is detachably attached to at least one of the roof member 11 and the sensor cover 17 with fastening members (not shown).

A front end and a rear end of the external cover 21 are respectively open. The open part at the front end of the external cover 21 includes a portion around the front end of the top 17b of the sensor cover 17. This portion forms an intake port 22 for drawing in air from the outside of the vehicle 10. Also, the open part at the rear end of the external cover 21 includes a portion around the rear end of the sensor cover 17. This portion forms an outlet port 23 for discharging air to the outside of the vehicle 10. The gap G1 is located between the intake port 22 and the outlet port 23 and is connected to the intake port 22 and the outlet port 23.

### Decorative Component 25

As shown in FIGS. 3, 5, and 6, the decorative component 25 includes a base 26, a closing portion 27, and attachment portions 28. In the decorative component 25, at least the base 26 and the closing portion 27 are made of a plastic material that permits passage of the infrared rays 15. The base 26 and the closing portion 27 include a transmission limiting layer (not shown) that limits passage of visible light by reflecting or absorbing visible light. The transmission limiting layer for visible light includes, for example, a black-out layer. The black-out layer, for example, is formed by using a paint made from black pigments.

As in the case of the above-described opening 18, the base 26 and the closing portion 27 are each inclined relative to a horizontal plane and a vertical plane so as to be progressively shifted to the front toward the lower end. The base 26 is large enough to cover the opening 18 from the front. The closing portion 27 protrudes rearward from the base 26. The closing portion 27 is slightly smaller than the opening 18. The attachment portions 28 respectively protrude rearward from the upper end of the base 26.

As shown in FIGS. 3 and 5, the base 26 is disposed at a position adjacent to and in front of the opening 18, and the closing portion 27 is inserted into the opening 18 from the front. The closing portion 27 is disposed in the opening 18 to close most of the opening 18. An annular seal member 29 is arranged about the closing portion 27 to provide a seal between an inner circumferential wall surface of the opening 18 and an outer circumferential surface of the closing portion 27 (refer to FIG. 6).

Further, each attachment portion 28 is placed over the front end of the top 17b of the sensor cover 17. Each attachment portion 28 is detachably attached to the front end of the top portion 17b with a fastening member 31 such as a screw.

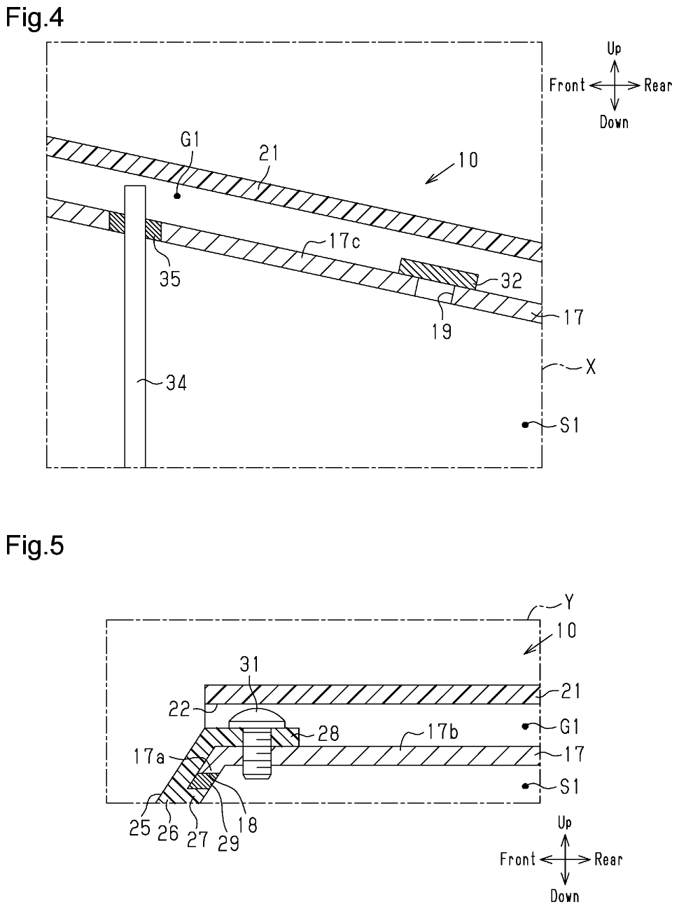

As shown in FIGS. 3 and 4, the vehicle upper structure according to the first embodiment further includes a connecting hole 19, a piece of air permeable adhesive tape 32, and a heat conductive member 34.

### Connecting Hole 19

The connecting hole 19 is provided in a part of the sensor cover 17 that is covered by the external cover 21. In the first embodiment, the connecting hole 19 is provided in the rear portion 17c. The connecting hole 19 extends through the rear portion 17c in the thickness direction (vertical direction). The connecting hole 19 connects a space S1 covered by the sensor cover 17 and the gap G1 to each other.

### Air Permeable Adhesive Tape 32

The air permeable adhesive tape 32 allows air and water vapor to pass therethrough, while restricting water from passing therethrough. The air permeable adhesive tape 32 is attached to part of at least one of the inner surface and the outer surface of the sensor cover 17 to close the opening of the connecting hole 19. In the first embodiment, the air permeable adhesive tape 32 is adhered to the outer surface of the rear portion 17c.

### Heat Conductive Member 34

The heat conductive member 34 has the shape of a rod and is made of a material having a higher thermal conductivity than that of the sensor cover 17. The heat conductive member 34 is disposed to extend through the rear portion 17c in the vertical direction. The heat conductive member 34 is arranged to extend over the space S1 and the gap G1. The upper end of the heat conductive member 34 is disposed in the gap G1. A seal member 35 is disposed between the heat conductive member 34 and the part of the sensor cover 17 through which the heat conductive member 34 extends. The gap between the inner wall surface of the portion of the sensor cover 17 through which the heat conductive member 34 extends and the part of the outer circumferential surface of the heat conductive member 34 that extends through the sensor cover 17 is filled with and sealed by the seal member 35.

Operation of the first embodiment, which is configured as described above, will now be described.

### Protection of Sensor 16

When an external force is applied to the vehicle upper structure shown in FIG. 3 from the outside of the vehicle, for example, from above, the external force is first applied to the external cover 21. If the external force is relatively small, the external force is received by the external cover 21.

Depending on the magnitude of the external force, the external cover 21 may be bent or deformed. However, if the external cover 21 is bent or deformed in the gap G1, the external force is not transmitted to or is unlikely to be transmitted to the sensor cover 17.

Further, if the external cover 21 is bent or deformed beyond the gap G1 by the external force, the external cover 21 is received by the sensor cover 17. At this time, the sensor cover 17 receives the external cover 21 without being deformed or with a relatively small amount of deformation.

Particularly, the sensor cover 17 is made of a metal material and has a higher strength than that in a case in which the sensor cover 17 is made of a plastic material. The sensor cover 17 is thus capable of receiving the external cover 21 without being deformed or with a relatively small amount of deformation.

This limits the transmission of the external force to the sensor 16, which improves the performance in protecting the sensor 16 from the external force.

### Improvement of Appearance by Decorative Component 25

When the decorative component 25 is irradiated with visible light from the front of the vehicle 10, the transmission limiting layer, which includes, for example, a black-out layer, limits transmission of the visible light through the decorative component 25.

### Recognition of External Environment by Sensor 16

If the decorative component 25 were made of a metal material, the infrared rays 15 would be reflected by the decorative component 25 and thus unable to readily pass through the decorative component 25.

In this regard, in the first embodiment, the decorative component 25 is made of a plastic material that permits passage of the infrared rays 15.

Thus, when the infrared rays 15 are emitted forward from the sensor 16 as shown in FIG. 3, the infrared rays 15 pass through the decorative component 25. After passing through the decorative component 25, the infrared rays 15 hit and are reflected by an object outside the vehicle, such as a leading vehicle or a pedestrian, or the like, again pass through the decorative component 25, and are received by the sensor 16. The sensor 16 obtains information of the external environment of the vehicle 10 from the emitted and received infrared rays 15. For example, an object may be recognized, and the distance between the vehicle 10 and the object, the relative velocity, and the like may be detected.

### Waterproofing

As shown in FIGS. 3 and 6, the vehicle upper structure includes the opening 18, for example, in the front portion 17a of the sensor cover 17. Thus, rain, snow, or the like may enter the space S1 through the opening 18 and collect on the sensor 16. If rain, snow, or the like collects on the sensor 16, the detection performance of the sensor 16 may be reduced.

In this regard, the base 26 of the decorative component 25 is larger than the opening 18 and covers the opening 18 from the front. The base 26 restricts rain, snow or the like from entering the opening 18 (waterproofing).

Also, the closing portion 27 of the decorative component 25 is inserted into the opening 18 to close most of the opening 18. The closing portion 27 further restricts rain, snow, or the like from entering the opening 18, thereby improving the waterproofing performance.

Further, in the first embodiment, the seal member 29 provides a seal between the inner circumferential wall surface of the opening 18 and the outer circumferential surface of the closing portion 27. This further improves the waterproofing performance.

Even if water enters the gap G1 through the intake port 22, the air permeable adhesive tape 32 restricts the water from entering the space S1 through the connecting hole 19. This also improves the waterproofing performance. The water that has entered the gap G1 flows rearward along the inclination of the rear portion 17c of the sensor cover 17, and is then discharged to the outside of the vehicle through the outlet port 23.

### Cooling of Sensor 16

As the sensor 16 is activated, the sensor 16 generates heat, which increases the temperature of the sensor 16. Accordingly, the heat is trapped in the space S1, which increases the temperature of the space S1. If the increased temperature of the sensor 16 exceeds the guaranteed operating temperature range of the sensor 16, the operation of the sensor 16 may be unstable.

In this regard, in the first embodiment, for example, as illustrated in FIG. 3, when the vehicle 10 travels forward in the emission direction of electromagnetic waves, specifically, when the vehicle 10 travels forward, relatively cold air outside the vehicle 10 enters the gap G1 through the intake port 22. The air that has entered the gap G1 flows rearward, and is then discharged to the outside of the vehicle 10 through the outlet port 23. The heat of the space S1 is conducted to the air flowing through the gap G1 via the sensor cover 17. This heat conduction cools the space S1 and the sensor 16. This suppresses an increase in temperature of the sensor 16 and restricts the temperature of the sensor 16 from exceeding the guaranteed operating temperature range of the sensor 16.

Also, the heat of the space S1 is transferred to a portion of the heat conductive member 34 that is located in the space S1. This heat is conducted to a portion (upper end) of the heat conductive member 34 that is disposed in the gap G1. This heat is transferred to the air flowing through the gap G1 and is discharged to the outside of the vehicle 10 from the outlet port 23 together with the air. This promotes cooling of the space S1 and the sensor 16.

Further, when the humidity in the space S1 increases, water vapor (moisture) passes through the connecting hole 19 and the air permeable adhesive tape 32 and is discharged to the gap G1. The water vapor (moisture) flows along with the air flowing through the gap G1 and is discharged to the outside of the vehicle 10 through the outlet port 23.

### Repairability

If a structure were employed in which the decorative component 25 is fixed to the sensor cover 17, it would be difficult to address damages to the decorative component 25 caused by flying pebbles or similar objects.

In this regard, the first embodiment is capable of addressing damages to the decorative component 25. To address such damages, the external cover 21 is detached from one of the roof member 11 and the sensor cover 17 to which the external cover 21 has been attached. The decorative component 25 can be detached from the sensor cover 17 by loosening the fastening by the fastening member 31. The detached decorative component 25 is repaired and then attached to the sensor cover 17 by fastening the fastening member 31. In addition, instead of the detached decorative component 25, another decorative component 25 may be attached to the sensor cover 17.

The first embodiment has the following advantages.

(1-1) As shown in FIG. 3, the sensor cover 17, which covers the sensor 16, is covered from the outside by the external cover 21 in the first embodiment. This prevents external force from being transmitted to the sensor 16. Compared to other typical configurations in which the sensor is covered with only an opening member, the performance of protecting the sensor 16 from external force is improved.

(1-2) As shown in FIG. 3, in the first embodiment, the sensor cover 17 is covered from the outside by the external cover 21 with the gap G1 between the sensor cover 17 and the external cover 21. This further restricts transmission of external force to the sensor cover 17 and the sensor 16, further improving the advantage (1-1).

(1-3) As shown in FIG. 6, the sensor cover 17 is made of a metal material in the first embodiment. Thus, as compared with a case in which the sensor cover 17 is made of a plastic material, the performance of protecting the sensor 16 with the sensor cover 17 from external force is improved.

(1-4) As shown in FIGS. 3 and 6, in the first embodiment, the decorative component 25, which is made of a plastic material and permits passage of the infrared rays 15, is disposed in front of the sensor 16. Thus, the infrared rays 15 emitted from the sensor 16 pass through the decorative component 25. This allows the sensor 16 to recognize the external environment.

(1-5) In the first embodiment, the decorative component 25 includes the transmission limiting layer (not shown) for visible light. Thus, when the vehicle 10 is viewed from the front, the sensor 16 will not be visible through the decorative component 25 since the sensor 16 is shielded by the decorative component 25. The appearance of the vehicle upper structure, in particular, the appearance around the sensor 16 is improved as compared to a case in which the sensor 16 is visible through the decorative component 25.

(1-6) As shown in FIGS. 3 and 5, in the first embodiment, the opening 18 in front of the sensor 16 is covered by the base 26 of the decorative component 25 from the front. This restricts entry of rain, snow, or the like into the space S1 through the opening 18 (waterproofing).

(1-7) In the first embodiment, most of the opening 18 is closed by the closing portion 27 of the decorative component 25. This improves the waterproofing performance described in the advantage (1-6).

(1-8) In the first embodiment, the annular seal member 29 is disposed around the closing portion 27 to provide a seal between the inner circumferential wall surface of the opening 18 and the outer circumferential surface of the closing portion 27. This further improves the waterproofing performance described in the advantage (1-6).

(1-9) As shown in FIGS. 5 and 6, the fastening member 31 such as a screw is used to detachably attach the decorative component 25 to the top 17b of the sensor cover 17 in the first embodiment. This improves the repairability as compared to a case in which the decorative component 25 is fixed to at least one of the sensor cover 17, the external cover 21, or the roof member 11.

(1-10) As shown in FIG. 3, in the first embodiment, a part of the opening at the front end of the external cover 21, specifically, a part about the front end of the top 17b of the sensor cover 17 is used as the air intake port 22. Also, a part of the open part at the rear end of the external cover 21, specifically, a part about the rear end of the sensor cover 17 is used as the air outlet port 23. The gap G1 is connected to the intake port 22 and the outlet port 23.

Therefore, when the vehicle 10 is, for example, traveling forward, the air outside the vehicle 10 is drawn into the gap G1 through the intake port 22 to flow through the gap G1 and then discharged out of the vehicle 10 from the outlet port 23. The heat of the space S1 is conducted to the air flowing through the gap G1 to cool the space S1 and the sensor 16. This limits an increase in temperature of the sensor 16 and improves the stability of the operation of the sensor 16.

(1-11) Related to the above-described advantage (1-10), since portions of the front and rear open parts of the external cover 21 that surround the sensor cover 17 form the intake port 22 and the outlet port 23, the intake port 22 and the outlet port 23 do not need to be provided separately.

(1-12) As shown in FIG. 4, the sensor cover 17 has the connecting hole 19 in the rear portion 17c in the first embodiment. The air permeable adhesive tape 32 is adhered to a part of the outer surface of the rear portion 17c that closes the opening of the connecting hole 19. Therefore, even if water enters the gap G1 through the intake port 22, the water is restricted from entering the space S1 through the connecting hole 19, and water vapor (moisture) in the space S1 is discharged to the gap G1 through the connecting hole 19. The water vapor (moisture) is then carried by the air flowing through the gap G1 and discharged from the outlet port 23 to the outside of the vehicle 10.

(1-13) As shown in FIG. 4, the heat conductive member 34, which has a higher thermal conductivity than the sensor cover 17, is disposed to extend over the space S1 and the gap G1 in the first embodiment. Thus, the heat of the space S1 is conducted to the gap G1 through the heat conductive member 34 and is discharged from the outlet port 23 together with the air flowing through the clearance G1. This promotes cooling of the space S1 and the sensor 16. As a result, an increase in temperature of the sensor 16 is further limited, and the advantage (1-10) is further improved.

(1-14) As shown in FIG. 3, the external cover 21 is made of a plastic material in the first embodiment. Thus, as compared with a case in which the external cover 21 is made of a metal material, the external cover 21 is reduced in weight. This reduces the weight of the vehicle upper structure and thus the weight of the vehicle 10.

### SECOND EMBODIMENT

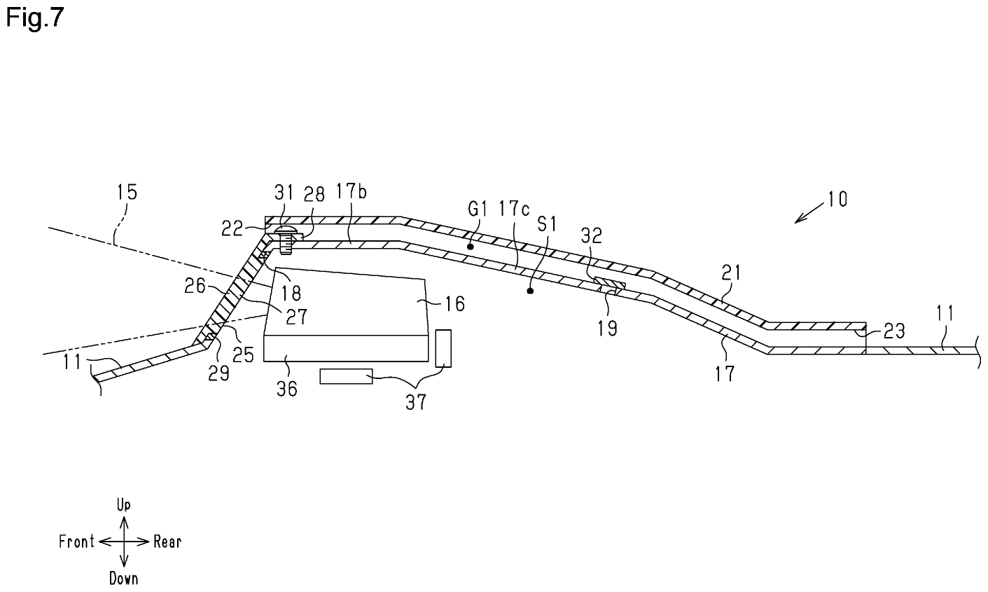

A vehicle upper structure according to a second embodiment will now be described with reference to FIG. 7.

The second embodiment differs from the first embodiment in the structure for cooling the sensor 16. Specifically, a heat sink 36 is disposed at a position adjacent to the sensor 16. In the second embodiment, the heat sink 36 is disposed at a position adjacent to and below the sensor 16.

The heat sink 36 receives some of the heat of the sensor 16 and discharges the heat into the air and the like. The heat sink 36 is made of material such as ceramics and metal (for example, aluminum) having a relatively high thermal conductivity. The heat sink 36 has a structure that increases the surface area. For example, the heat sink 36 has a structure including plate-shaped portions, which are referred to as fins, and thin rod-shaped portions. The heat sink 36 may be disposed such that at least part of the heat sink 36 is located below the roof member 11.

Furthermore, fans 37 are provided near the heat sink 36 in the second embodiment. Each fan 37 rotates its blades with an electric motor to guide air to the heat sink 36, thereby increasing the amount of air passing through the heat sink 36.

Although the heat conductive member 34 is not used in the second embodiment, it may be used.

The configuration, other than the above, is the same as the first embodiment. Thus, in the second embodiment, the same components as those in the first embodiment are given the same reference numerals, and detailed explanations are omitted.

Thus, among the operations described in the first embodiment, the operations except for the operation of the heat conductive member 34 are also performed in the second embodiment.

In addition, in the second embodiment, the following operation is performed for cooling the sensor 16.

Some of the heat of the sensor 16 is transferred to the heat sink 36, and is released into the air from the heat sink 36. This limits an increase in the temperature of the sensor 16.

The operation of the fan 37 also increases the amount of air passing through the heat sink 36. This increases the amount of heat released from the heat sink 36 into the air.

The second embodiment has the following advantages. The second embodiment has the same advantages as those of the first embodiment, except for the advantage (1-13), which is achieved by using the heat conductive member 34. In addition, the second embodiment achieves the following advantages.

(2-1) In the second embodiment, the heat sink 36 is disposed at a position adjacent to the sensor 16. This limits an increase in temperature of the sensor 16 and improves the stability of the operation of the sensor 16.

(2-2) In the second embodiment, the amount of air passing through the heat sink 36 is increased by the fans 37. This further limits an increase in temperature of the sensor 16, thereby further improving the advantage (2-1).

### THIRD EMBODIMENT

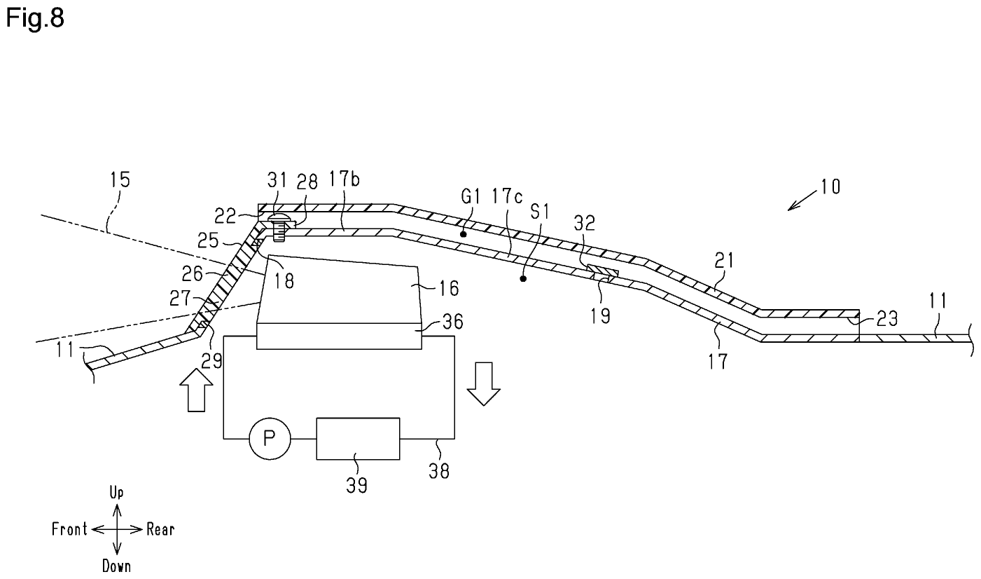

A vehicle upper structure according to a third embodiment will now be described with reference to FIG. 8.

In the third embodiment, the above-described fans 37 are replaced by a cooling passage 38 through which coolant flows. The cooling passage 38 is annular (endless). The cooling passage 38 is formed by an internal space of piping members (not shown) arranged in the vehicle 10. Part of the cooling passage 38 is disposed in the heat sink 36. A pump P and a radiator 39 are disposed in the cooling passage 38. The pump P circulates the coolant in the cooling passage 38. The radiator 39 cools the coolant by dissipating the heat of the coolant into the air. Part of the cooling passage 38, the radiator 39, the pump P, and the like may be disposed at positions in the vehicle 10 that are away from the roof member 11.

The configuration, other than the above, is the same as the second embodiment. Thus, in the third embodiment, the same components as those in the second embodiment are given the same reference numerals, and detailed explanations are omitted.

Thus, among the operations described in the second embodiment, the operations except for the operation of the fans 37 are also performed in the third embodiment. In addition, in the third embodiment, the following operation is performed for cooling the sensor 16.

The pump P circulates the coolant in the cooling passage 38 as indicated by the blank arrows in FIG. 8. The heat of the coolant is dissipated into the air as the coolant passes through the radiator 39. The dissipation of the heat causes the temperature of the coolant to be lower than before passing through the radiator 39. The coolant with the lowered temperature passes through the heat sink 36. The heat sink 36 receives some of the heat generated by the sensor 16 and releases the heat to the air or to the coolant that passes through part of the cooling passage 38 located inside the heat sink 36. The release of the heat cools the sensor 16 and causes the temperature of the coolant to be higher than that before passing through the heat sink 36. The coolant with the increased temperature flows through the cooling passage 38 so as to be returned to the radiator 39.

The third embodiment has the following advantages. The third embodiment has the same advantages as those of the second embodiment, except for the advantage (2-2), which is achieved by using the fans 37. In addition, the third embodiment achieves the following advantage.

(3-1) The third embodiment includes the cooling passage 38, through which coolant flows, and part of the cooling passage 38 is disposed in the heat sink 36. This allows some of the heat released from the heat sink 36 to be transferred to the coolant, so that the temperature of the sensor 16 is further restricted from increasing. Accordingly, the advantage (2-1) is further improved.

### FOURTH EMBODIMENT

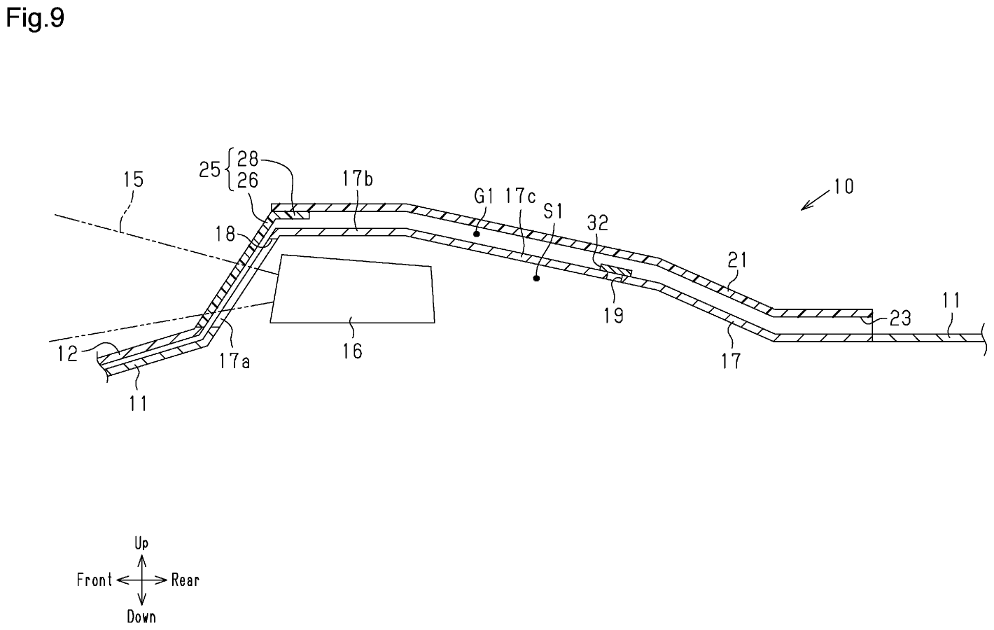

A vehicle upper structure according to a fourth embodiment will now be described with reference to FIG. 9.

The fourth embodiment uses a decorative component 25 having a shape different from that of the first embodiment. The decorative component 25 includes a base 26 and attachment portions 28. The decorative component 25 does not include the closing portion 27. Although not closed by the decorative component 25, the opening 18 is covered by the base 26, which is larger than the opening 18, from the front.

In the decorative component 25, at least the base 26 is made of a plastic material that permits passage of the infrared rays 15. The base 26 includes a transmission limiting layer (not shown) for visible light as in the first embodiment.

Like the above-described front portion 17a, the base 26 is inclined relative to a horizontal plane and a vertical plane at a position in front of the front portion 17a so as to be progressively shifted to the front toward the lower end. The attachment portions 28 respectively protrude rearward from the upper end of the base 26.

The decorative component 25 is attached to the front end of the external cover 21 at the attachment portions 28. This attachment may be achieved using an adhesive or similar fixing method. Alternatively, the method of attachment may involve fastening with screws or other fastening members, similar to the first embodiment. In the latter case, the decorative component 25 is detachably attached to the front end of the external cover 21 at the attachment portions 28.

In FIG. 9, an auxiliary roof member 12, which forms the roof of the vehicle 10 together with the roof member 11, is disposed below and in front of the base 26. However, the auxiliary roof member 12 may be omitted.

Although the heat conductive member 34 is not used in the fourth embodiment, it may be used.

Although not illustrated in FIG. 9, an air intake port is formed at least one side of the decorative component 25 in the lateral direction. As in the first embodiment, the intake port is connected to the gap G1.

The configuration, other than the above, is the same as the first embodiment. Thus, in the fourth embodiment, the same components as those in the first embodiment are given the same reference numerals, and detailed explanations are omitted.

Thus, among the operations described in the first embodiment, the operations except for the operations of the heat conductive member 34, the closing portion 27, and the seal member 29 are also performed in the fourth embodiment. The fourth embodiment is slightly different from the first embodiment in the order of transmission of the infrared rays 15 since the decorative component 25 is attached to the external cover 21 and the base 26 is disposed in front of the opening 18.

When the sensor 16 emits the infrared rays 15 forward, the infrared rays 15 pass through the base 26 of the decorative component 25 after passing through the opening 18. After passing through the base 26, the infrared rays 15 hit and are reflected by an object outside the vehicle, such as a leading vehicle or a pedestrian, and then pass through the base 26 again. Thereafter, the infrared rays 15 pass through the opening 18 and are received by the sensor 16. The sensor 16 obtains information of the external environment of the vehicle 10 based on the emitted and received infrared rays 15.

The fourth embodiment has the following advantages. The fourth embodiment has the same advantages as those of the first embodiment, except for the advantages (1-7), (1-8), and (1-13). Particularly, when the attachment portions 28 are detachably attached to the front end of the external cover 21 by means of fastening members, the repairability is improved as in the case of the above described advantage (1-9).

The above-described embodiments may be modified as follows. The above-described embodiments and the following modifications can be combined as long as the combined modifications remain technically consistent with each other.

### Modification of Sensor 16

The sensor 16 may recognize the external environment by emitting and receiving electromagnetic waves other than infrared rays. The sensor 16 may be, for example, a millimeter wave radar device that uses millimeter waves as electromagnetic waves. The sensor 16 may be various types of camera devices.

The sensor 16 may recognize the external environment behind the vehicle 10 by emitting electromagnetic waves rearward from the vehicle 10 and receiving the electromagnetic waves that have struck and been reflected by an object outside the vehicle 10.

The sensor 16 may be arranged at a position different from the front part of the roof member 11 in the front-rear direction, for example, at the center of the rear part of the roof member 11.

The sensor 16 may be mounted in the upper part of the vehicle 10 such that a part of the sensor 16 is located below the roof member 11.

### Modification of Sensor Cover 17 and External Cover 21

The sensor cover 17 may be made of a plastic material instead of a metal material. In this case, the sensor cover 17 is lighter than in a case in which the sensor cover 17 is made of a metal material. Accordingly, the weight of the vehicle upper structure and thus the weight of the vehicle 10 are reduced.

In contrast to the above-described embodiments, the sensor cover 17 may be made of a plastic material, and the external cover 21 may be made of a metal material.

A fastening member different from the above-described screws may be used to detachably attach the decorative component 25 to the sensor cover 17 or the external cover 21. Further, a member different from a fastening member may be used for the detachable attachment.

In each of the above-described embodiments, the opening 18 is formed between the front portion 17a of the sensor cover 17 and a portion of the roof member 11 that is adjacent to and forward of the front portion 17a. Instead, the entire opening 18 may be formed in the front portion 17a.

The sensor cover 17 may be modified as long as the sensor cover 17 covers at least a part of the sensor 16 that is above the roof member 11. Thus, the sensor cover 17 may cover a part of the sensor 16 that is located below the roof member 11 in addition to a part of the sensor 16 that is located above the roof member 11.

The inclination of the front portion 17a of the sensor cover 17 may be changed to a manner different from those in the first to fourth embodiments.

For example, the inclination of the front portion 17a may be changed to an inclination that is inclined relative to a horizontal plane and a vertical plane at an angle different from those in the first to fourth embodiments.

The inclination of the front portion 17a may be changed such that the front portion 17a is not inclined but is parallel with the vertical plane (orthogonal to the horizontal plane).

In the first to third embodiments, the manner in which the base 26 and the closing portion 27 of the decorative component 25 are inclined is changed in accordance with the above-described modification. Further, in the fourth embodiment, the manner in which the base 26 is inclined in the decorative component 25 is changed in accordance with the above-described modification.

### Modification of Connecting Hole 19 and Air Permeable Adhesive Tape 32

The connecting hole 19 may be provided at a position in the sensor cover 17 different from the rear portion 17c as long as the connecting hole 19 is covered by the external cover 21.

Instead of or in addition to the outer surface of the sensor cover 17, the air permeable adhesive tape 32 may be adhered to a part of the inner surface that closes the opening of the connecting hole 19.

The sensor cover 17 may include connecting holes 19 at multiple positions, and the air permeable adhesive tape 32 may be adhered to portions of the sensor cover 17 that close the openings of the connecting holes 19.

The connecting hole 19 may be omitted. In this case, the air permeable adhesive tape 32 is also omitted.

### Modification of Decorative Component 25

The decorative component 25 may be detachably attached to at least one of the sensor cover 17, the external cover 21, and the roof member 11.

Thus, the decorative component 25 may be detachably attached to the roof member 11 instead of the sensor cover 17 and the external cover 21. Further, the decorative component 25 may be detachably attached to two or three of the sensor cover 17, the external cover 21, and the roof member 11.

In contrast, the decorative component 25 may be fixed to at least one of the sensor cover 17, the external cover 21, and the roof member 11.

The decorative component 25 may be omitted.

The transmission limiting layer in the decorative component 25 may be omitted.

### Modification of Heat Conductive Member 34

A shape different from that of the first embodiment, specifically, a non-rod shape, may be used for the heat conductive member 34.

As long as the heat conductive member 34 extends through a portion of the sensor cover 17, the heat conductive member 34 may extend through a portion of the sensor cover 17 different from the sensor cover 17.

Multiple heat conductive members 34 may be used.

The heat conductive member 34 may be omitted.

### Modification of Heat Conductive Member 34 and Heat Sink 36

In the first embodiment, similarly to the second and third embodiments, a heat sink 36 may be disposed at a position adjacent to the sensor 16. In this case, part of the heat conductive member 34 disposed in the space S1, such as the lower end, may be attached to the heat sink 36. In this modification, the heat released from the heat sink 36 is conducted to the air flowing through the gap G1 via the heat conductive member 34. This efficiently cools the sensor 16.

### Another Modification

The second and third embodiments may be combined. That is, the fans 37 may be provided near the heat sink 36, and part of the cooling passage 38 may be disposed inside the heat sink 36.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A vehicle upper structure, comprising:
a roof member of a vehicle;
a sensor mounted on an upper part of the vehicle such that at least part of the sensor is located above the roof member, the sensor being configured to emit and receive electromagnetic waves to recognize an external environment of the vehicle;
a sensor cover that covers at least the part of the sensor that is above the roof member; and
an external cover that covers the sensor cover from outside with a gap between the external cover and the sensor cover.

2. The vehicle upper structure according to claim 1, wherein, of the sensor cover and the external cover, at least the external cover is made of a plastic material.

3. The vehicle upper structure according to claim 2, wherein the sensor cover is made of a metal material.

4. The vehicle upper structure according to claim 1, wherein
the sensor is configured to emit and receive infrared rays as the electromagnetic waves to recognize the external environment of the vehicle,
the vehicle upper structure further comprises a decorative component that limits passage of visible light and permits passage of the infrared rays, and
the decorative component is arranged at a position in front of the sensor in an emission direction of the infrared rays.

5. The vehicle upper structure according to claim 4, wherein the decorative component is detachably attached to at least one of the sensor cover, the external cover, and the roof member.

6. The vehicle upper structure according to claim 1, wherein
a front end and a rear end of the external cover in an emission direction of the electromagnetic waves are respectively open,
a portion of an open part at the front end around the sensor cover forms an intake port for drawing in air from the outside of the vehicle,
a portion of an open part at the rear end around the sensor cover forms an outlet port for discharging air to the outside of the vehicle, and
the gap is connected to the intake port and the outlet port.

7. The vehicle upper structure according to claim 6, wherein
the sensor cover includes a connecting hole in a section that is covered by the external cover, the connecting hole connecting a space covered by the sensor cover to the gap, and
a piece of air permeable adhesive tape is provided on at least one of an inner surface and an outer surface of the sensor cover to close an opening of the connecting hole, the air permeable adhesive tape allowing air and water vapor to pass therethrough, while restricting water from passing therethrough.

8. The vehicle upper structure according to claim 6, further comprising a heat conductive member having a higher thermal conductivity than that of the sensor cover,
wherein the heat conductive member is disposed to extend over a space covered by the sensor cover and the gap.

9. The vehicle upper structure according to claim 1, further comprising a heat sink disposed at a position adjacent to the sensor.

10. The vehicle upper structure according to claim 9, further comprising a fan configured to increase an amount of air that passes through the heat sink.

11. The vehicle upper structure according to claim 9, further comprising a cooling passage through which a coolant flows,
wherein a part of the cooling passage is located inside the heat sink.
